(19) United States
(12) Patent Application Publication
(10) Pub. No.: US 2013/0062633 A1
(43) Pub. Date: Mar. 14, 2013

(54) LED Array Having Embedded LED and Method Therefor

(71) Applicant: Randolph Cary DEMUYNCK, Wake Forest, NC (US)

(72) Inventor: Randolph Cary DEMUYNCK, Wake Forest, NC (US)

(21) Appl. No.: 13/417,972

(22) Filed: Mar. 12, 2012

Related U.S. Application Data
(63) Continuation-in-part of application No. 13/088,693, filed on Apr. 18, 2011.

(51) Int. Cl. H01L 33/08; H01L 33/44

(52) U.S. Cl. 257/88; 438/29; 257/E33.061

(57) ABSTRACT

A light emitting array comprises a submount having a top surface and a bottom surface, and at least one LED at least partially embedded within the submount. The top surface of the submount is in contact with at least a side surface of the at least one LED. The submount may include one or more parallel layers. An optical layer may be covering the at least one LED in such a way that light emitted from the at least one LED passes through the optical layer.

### CROSS-REFERENCE TO RELATED APPLICATIONS

This application is a continuation-in-part of U.S. Utility patent application Ser. No. 13/088,693, filed Apr. 18, 2011 and entitled “LED Array Having Embedded LED and Method Therefor”, which is incorporated herein by reference in its entirety.

### FIELD OF INVENTION

This invention relates to light emitting diodes (LED or LEDs) and in particular to LED packages having an LED embedded within the package.

### BACKGROUND

Light emitting diodes (LED or LEDs) are solid state devices that convert electric energy to light and generally comprise one or more active layers of semiconductor material sandwiched between oppositely doped layers. When a bias is applied across the doped layers, holes and electrons are injected into the active layer where they recombine to generate light. Light is emitted from the active layer and from all surfaces of the LED.

In order to use an LED in a circuit or other arrangement, it is known to enclose an LED in a light emitting array to provide environmental and/or mechanical protection, color selection, focusing and the like. A light emitting array also includes electrical leads, contacts or traces, for electrically connecting the LEDs. The LED is traditionally mounted upon the carrier, submount, or substrate of the light emitting array. As illustrated in FIG. 1a, a conventional LED package 110 includes an LED chip 112 mounted on a reflective cup 113 by means of a solder bond or conductive epoxy. One or more wire bonds 111 connect the ohmic contacts of the LED chip 112 to leads 115A and/or 115B, which may be attached to or integral with the reflective cup 113. The reflective cup 113 may be filled with an encapsulant material 116 containing a wavelength conversion material such as phosphor. Light emitted by the LED at a first wavelength may be absorbed by the phosphor, which may responsively emit light at a second wavelength. The entire assembly is then encapsulated in a clear protective resin 114, which may be molded in the shape of a lens to collimate the light emitted from the LED chip 112. While the reflective cup 113 may direct light in an upward direction, optical losses may occur when the light is reflected (i.e. some light may be absorbed by the reflector cup instead of being reflected). In addition, heat retention may be an issue for a package such as the package 110 shown in FIG. 1A, since it may be difficult to extract heat through the leads 115A, 115B.

A second conventional LED package 120 is shown in FIG. 1b. One or more LEDs 122 are mounted onto a carrier such as a printed circuit board (PCB) carrier, substrate or submount 123. A metal reflector 124 mounted on the submount 123 surrounds the LED 122 and reflects light emitted by the LED 122 away from the package 120. The reflector 124 also provides mechanical protection to the LED 122. One or more wire bond connections 111 are made between ohmic contacts on the LED 122 and electrical traces 125A, 125B on the carrier 123. The mounted LED is then covered with an encapsulant 126, which may provide environmental and mechanical protection to the LED while also acting as a lens. The metal reflector 124 is typically attached to the carrier 123 by means of a solder or epoxy bond.

FIG. 2 provides another example of a conventional LED package 130. As shown, a single LED 134 is mounted on a submount 132. The submount 132 has a top surface 136 comprising patterned conductive traces that may include a die attach pad 138 with an integral first contact pad 140. A second contact pad 142 is also included on the top surface 136 of the submount 132, with the LED 134 mounted approximately at the center of the attach pad 138. The LED 134 includes a conductive structure 144 and wire bond pads 146 on its top surface 136. An optical element or lens 148 is formed on the top surface 136 of the submount 132 over the LED 134, to provide both environmental and/or mechanical protection. An electrical signal is applied to the LED 134 through the second pad 142 and the first pad 140, with the electrical signal on the first pad 140 passing directly to the LED 134 through the attach pad 138 and the signal from the second pad 142 passing into the LED 134 through wire bonds. A solder mask 150 is included on the top surface 136 of the submount 132, at least partially covering the attach pad 138 and the first and second contact pads 140, 142. The LED package 130 includes two LED wire bonds 152 between a solder mask opening in the second connect pad 142 and wire bond pads 146 on the LED 134.

FIG. 3 shows another example of a conventional LED package 160. The LED package comprises a submount 162 for holding an array of LEDs 168. The submount 162 includes die pads 164 and conductive traces 166 are disposed on the top surface of the submount 162. LEDs 168 are included that comprise the LED array, with each of the LEDs 168 mounted to one of the respective die pads 164. Wire bonds 170 pass between the conductive traces 166 to each of the LEDs 168 with an electrical signal applied to each of the LEDs 168 through its respective one of the die pad 164 and the wire bond 170. A reflector 172 is mounted to the submount 162 around the LEDs 168. An optical element or lens 174 is included over the LEDs 168.

FIG. 4 shows another example of a conventional LED package 180. The LED package 180 comprises an array of LEDs 182 mounted on the surface of a submount 184. As shown, at least some of the LEDs 182 are interconnected in a series circuit. The LEDs 182 may be coated with a phosphor converter interconnected in a series circuit. The LEDs 182 are mounted on a substantially planar surface of the submount 184 and are arranged under a single optical lens element 186. The submount 184 may be formed of many different materials, including electrically insulating materials, such as a dielectric element.

In LED package design, two challenges are thermal management and size. It is known that thermal management is a concern with electronic packages, whether containing integrated circuits or discrete components such as diodes or power transistors. It is also known that excessive heat may cause LED failures. Thus, one of the considerations for designing LED packages is effective thermal management. One of the objectives of effective thermal management in the design of electronic packaging is to maintain the operating temperature of the LEDs and other active circuit components at an appropriately low enough temperature to prevent premature component failure. Various cooling strategies including conduction heat transfer are in common use. However, high intensity LEDs that emit light principally in the visible part of the electromagnetic spectrum can generate significant amounts of heat that is difficult to dissipate using conventional techniques. In conventional LED packages, heat from the LEDs mounted to a submount may pass into the submount below the LED, but may not efficiently spread laterally from below the LED. This increased heat can result in reduced lifetime or failure of the package.

There is also a continuous drive to reduce the size of LED packages to facilitate more widespread use of LEDs. With conventional LED packages, where LED arrays are formed from LEDs mounted to the surface of a submount, spacing between each individual LED in an array is dictated by the presence of the wire bond, which limits how close together the LEDs may be. In addition, these conventional LED packages provide for extended non-light emitting “dead space” between adjacent LEDs in an array. The LED package may also require additional optics or components, which may also increase the size of a LED array. The design considerations of reducing the size of an LED package and maintaining a relatively low operating temperature are to some extent competitive with each other. It is desirable to develop an LED package that addresses these design considerations.

### BRIEF SUMMARY

In an aspect of the present invention, a light emitting array comprises a submount having a top surface and a bottom surface and at least one LED at least partially embedded within the submount. The at least one LED may be embedded in the submount such that the top surface of the submount is in contact with a side surface of the at least one LED. In a further feature of the aspect, the at least one LED is completely embedded within the submount. The submount may comprise many different materials, with a preferred material being electrically insulating. The submount may comprise ceramic materials, organic insulators, epoxy resin, or pre-preg. In a feature of the aspect, the submount comprises transparent optic pre-preg. Examples of suitable pre-preg materials include FR-4 (Woven glass and epoxy), FR-5 (Woven glass and epoxy), FR-6 (Matte glass and polyester), G-10 (Woven glass and epoxy), CEM-3 (Woven glass and epoxy), CEM-4 (Woven glass and epoxy), and CEM-5 (Woven glass and polyester). The submount may include additional components embedded therein. The component may comprise drive circuitry.

In a further aspect, the submount of the light emitting array comprises one or more parallel layers. In a feature of the aspect, the one or more parallel layers may be disposed above and below the at least one LED. In a further feature of the aspect, electrically conductive planes are disposed between the one or more parallel layers of the light emitting array. The electrically conductive planes may be separated by layers of dielectric material, which may provide a plurality of electrical contacts for the light emitting array. In some aspects, the electrically conductive planes may also be embedded within the submount of the light emitting array. In a further feature of the aspect, the electrically conductive planes may comprise electrically conductive traces.

In another aspect, micro vias are disposed between the one or more parallel layers of the light emitting array. The micro vias may be used to facilitate electrical connection with the at least one LED. The micro vias may also be used to help with heat dissipation within the light emitting array. The micro vias may be disposed in a linear configuration or a non-linear configuration.

In a further aspect, one or more optical layers may cover the at least one LED in such a way that light emitted from the at least one LED passes through the one or more optical layers. The one or more optical layers may be disposed above or below the at least one LED. The one or more optical layers may comprise a transparent material, such as plastic, silicon, glass, epoxy-resin, and pre-preg materials. In some embodiments, the one or more optical layers may comprise transparent epoxy-resin. In other embodiments, the one or more optical layers may comprise transparent pre-preg.

In a feature of the aspect, the one or more optical layers may comprise one or more phosphor layers. The one or more phosphor layers may comprise particles embedded in the light emitting array or in a separate medium forming a layer in the light emitting array. Suitable phosphor materials include, but are not limited to, YAG, TAG, BOSE, and CaSrAlSiN₃. In another feature of the aspect, the one or more optical layers may comprise one or more luminescent layers comprising a transparent material having luminescent material dispersed therein. Suitable luminescent material may include phosphors, scintillators, day glow tapes and inks that glow in the visible spectrum upon illumination with ultraviolet light. In a further feature of the aspect, the one or more optical layers may comprise a luminescent layer comprising transparent pre-preg having phosphor dispersed therein. In another feature of the aspect, the one or more optical layers may include additional layers, including a filter layer, a spacer layer, a diffusion layer, and/or reflecting layers.

In another aspect, the light emitting array further comprises a conductive structure, such as a ground plane. The ground plane may provide the ground connections required by the light emitting array, and may also aid with heat dissipation. The ground plane may comprise suitable materials such as copper.

In a further aspect, a light emitting array comprises a base layer, at least one LED disposed on the base layer, one or more optical layers, and a substrate layer disposed below and in contact with the base layer in the array. The one or more optical layers cover the at least one LED and the base layer in such a way that light emitted from the at least one LED passes through the one or more optical layers. In another feature of the aspect, the light emitting array comprises a glue layer bonding the at least one LED to the base layer, wherein the glue layer overlies the base layer. The glue layer may comprise a reflective material. The base layer may comprise copper foil. A reflective layer may be disposed below the glue layer and the base layer. The reflective layer may have many different thicknesses and may comprise different reflective materials, with suitable materials including silver, aluminum, and gold, or any other reflective material such as barium sulfate and titanium dioxide. The at least one LED may be at least partially embedded within the substrate layer of the light emitting array. In another feature of the aspect, the at least one LED may comprise an array of LEDs. In some embodiments, the array of LEDs may be positioned in a planar arrangement within a single layer of the light emitting array. In alternative embodiments, the array of LEDs may be positioned within separate layers of the light emitting array.

In another aspect, spacing between the LEDs in the array is between about 40 microns to about 100 microns. In a further aspect, a surface effect resides on a surface of the one or more optical layers such that the array produces a predetermined light output. The surface effect may comprise a roughened surface region. The surface effect may comprise a surface pattern. In a feature of the aspect, the surface of the one or more optical layers may be finished, patterned, or processed. In another feature, the effect may be added to other layers within the light emitting array under the surface of the one or more optical layers.

In a further aspect, the light emitting array comprises a printed circuit board having at least one LED embedded therein. The printed circuit board may comprise multiple layers including a base layer, one or more substrate layers, one or more optical layers, and a ground plane. Additional components may be embedded within the multiple layers of the printed circuit board and/or mounted on outer surfaces of the printed circuit board. Electrical components may be packaged singly, such as resistors, capacitors, and transistors, or in groups, such as in amplifiers, oscillators, and integrated circuits. The electronic components may be mounted on the printed circuit board using surface mounted technology. The printed circuit board may include a positive voltage terminal and a negative voltage terminal.

In another aspect of the invention, a process for manufacturing a light emitting array comprises providing a submount having a top surface and a bottom surface and at least partially embedding at least one LED within the submount. The at least one LED may be embedded in the submount such that the top surface of the submount touches at least a side surface of the LED. In a further feature of the aspect, the at least one LED may be completely embedded within the submount. The light emitting array may comprise one or more layers. One or more components may be embedded within the light emitting array. The component may comprise driver circuitry.

In a feature of this aspect, the process further comprises drilling at least one conductive micro via in the submount. In another feature of this aspect, the process further comprises surrounding the at least partially embedded LED chip with one or more optical layers. In yet another feature, the light emitting array comprises a printed circuit board having at least one LED embedded therein.

### BRIEF DESCRIPTION OF THE DRAWINGS

The accompanying drawings are included to provide a further understanding of the invention and are incorporated in and constitute a part of this application. The drawings illustrate certain embodiment(s) of the invention. In the drawings:

FIG. 1a is a sectional view of an embodiment of a prior art LED package.

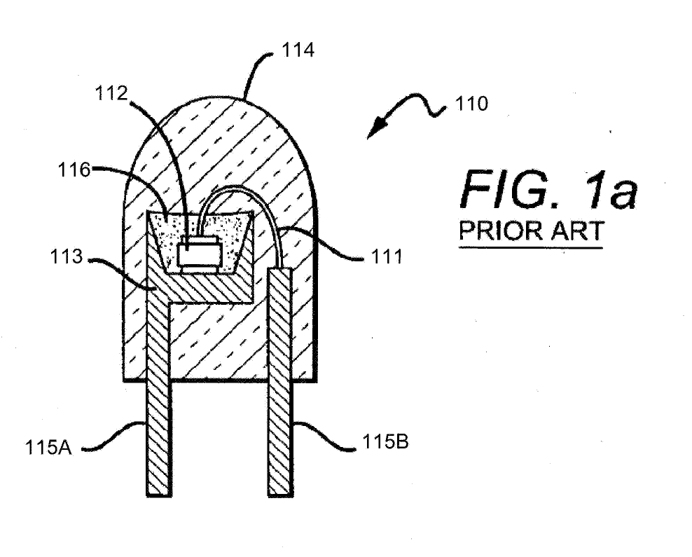

FIG. 1b is a sectional view of an alternative embodiment of a prior art LED package.

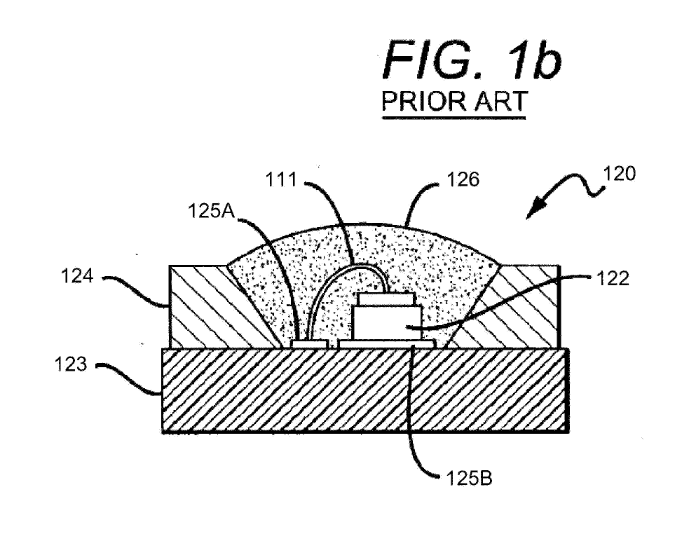

FIG. 2 is an upper perspective view of an alternative embodiment of a prior art LED package.

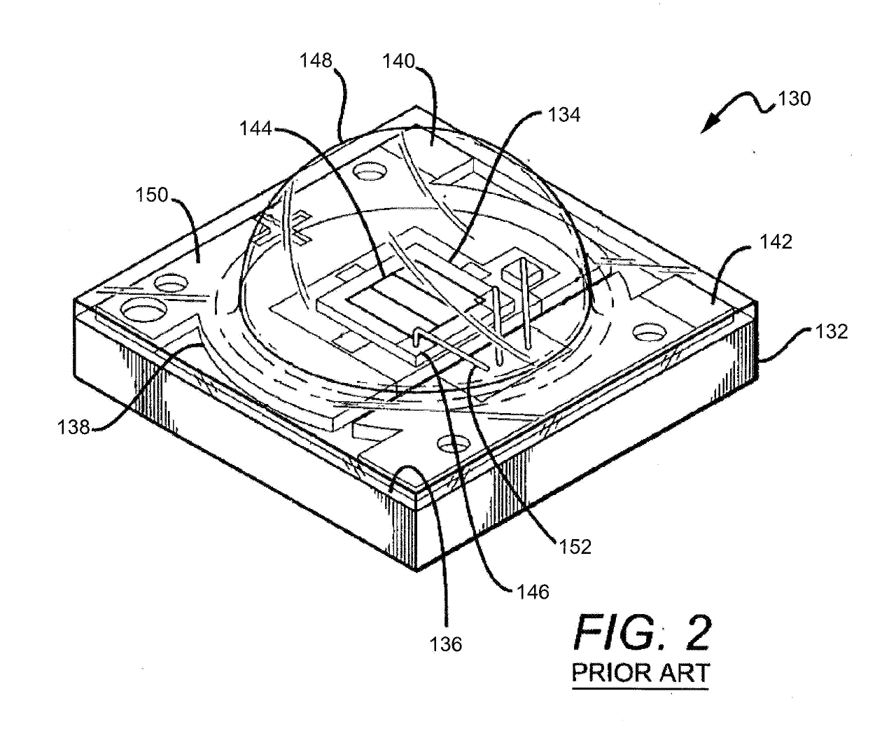

FIG. 3 is a sectional view of an alternative embodiment of a prior art LED package.

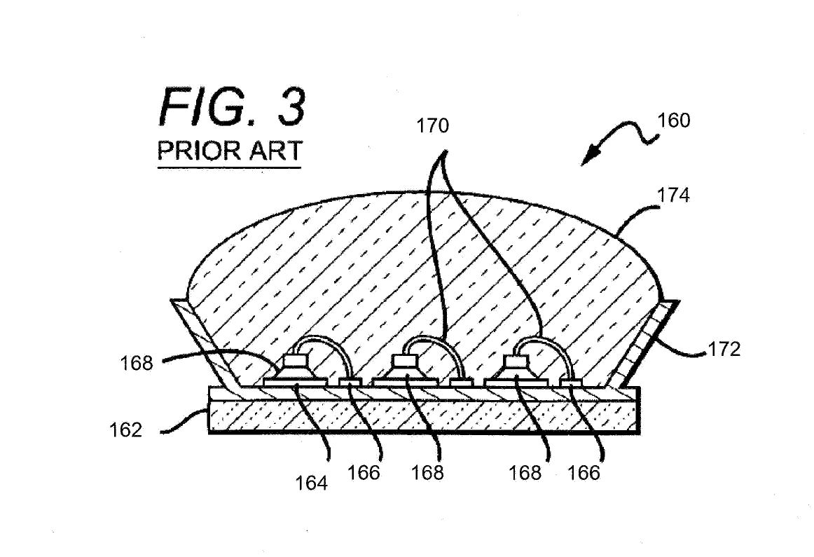

FIG. 4 is a sectional view of an alternative embodiment of a prior art LED package.

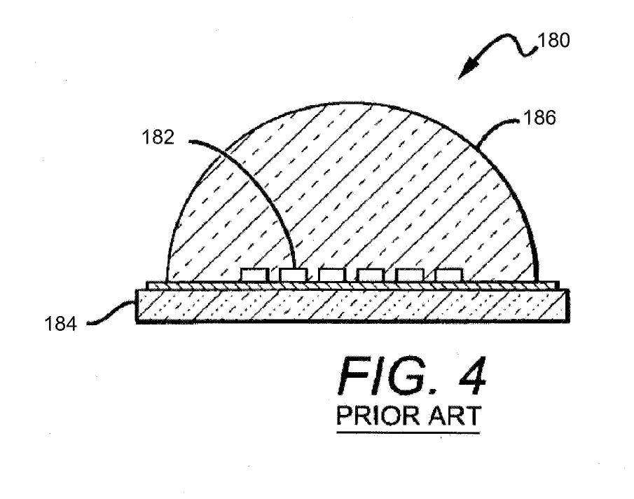

FIG. 5 is a side view schematic representation of an embodiment of a light emitting array in accordance with the present invention.

FIG. 6 is a side view schematic representation of the light emitting array of FIG. 5 with additional layers added to the array.

FIG. 7 is a schematic representation of a process for manufacturing a light emitting array in accordance with the present invention.

FIG. 8 is a side view schematic representation of an alternative embodiment of a light emitting array in accordance with the present invention.

FIG. 9 is a side view schematic representation of an alternative embodiment of a light emitting array in accordance with the present invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout. Optional elements are illustrated by dashed lines in the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer or region to another element, and/or layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

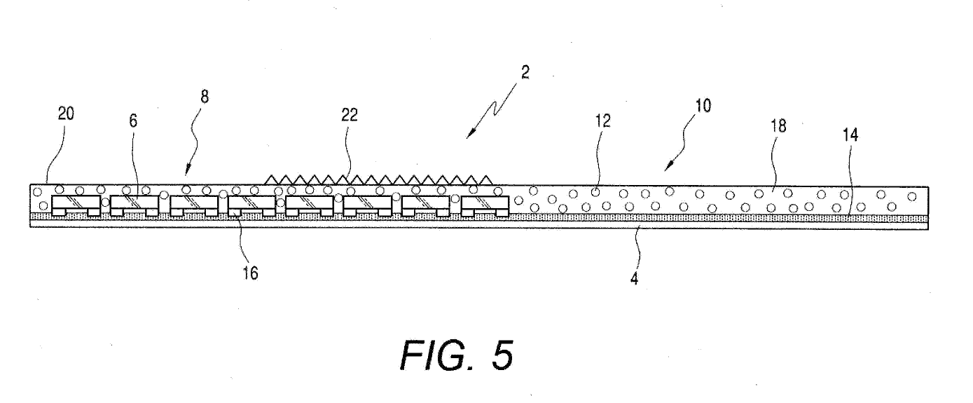

Reference is now made to FIG. 5. FIG. 5 is a side view schematic representation of an embodiment of a light emitting array in accordance with the present invention. In the embodiment of FIG. 5, the light emitting array 2 comprises a base layer 4, an array 8 of LEDs 6 disposed on the base layer 4, and an optical layer 10 covering the LED array 8 and the base layer 4. As shown, the optical layer 10 includes a luminescent material and covers the LED array 8 in such a way that light emitted from the LED array 8 passes through the optical layer 10.

The optical layer 10 may comprise one or more layers, such as a luminescent layer, a filter layer, a spacer layer and/or reflecting layers. In some embodiments, the optical layer 10 may comprise a luminescent layer having particles of a phosphor or multiple phosphors. In alternative embodiments, the optical layer 10 may comprise scattering particles, such as titanium dioxide. In additional embodiments, the optical layer 10 may comprise both phosphor and scattering particles. In other embodiments, the array 2 may comprise multiple optical layers 10. Additional layers, such as spacing layers and thermal paths may be added between, in, on, above or below the optical layers 10 in the array 2. One of skill in the art will understand that additional planes of electrical traces may be added to the array 2 to provide electrical connections to additional electrical circuitry on and/or embedded in the array 2.

As shown in FIG. 5, the LEDs 6 of the LED array 8 are embedded within the light emitting array 2. Conventionally, LEDs are mounted to the surface of a carrier, substrate or submount of the light emitting array. For example, one or more LEDs may be mounted to the surface of printed circuit boards. In contrast, in the light emitting array of the present invention, at least one LED is at least partially embedded into the array itself rather than being mounted to the surface of a submount. Embedding the at least one LED at least partially into the array provides design and operational advantages. For example, LEDs may be electrically connected using internal traces making up the LED array. As such, the LEDs may be arranged more closely to one another because wire bonding is not necessary for providing an electrical connection to the LED. Additionally, thermal management is aided because heat can be dissipated evenly throughout the optical layer and base layer. The optical layer may be constructed from a thermally conductive material to further aid in heat dissipation. Further, a ground plane may be added to the array to provide heat sinking. The size of the ground plane may be adjusted as needed for heat dissipation. An exemplary material of construction for the ground plane is copper penny. One of skill in the art will understand that various materials are available for use as a ground plane.

The base layer 4 of the array 2 may be constructed from a conductive metallic material. For example, the base layer 4 may be constructed from aluminum, iron, gold, or copper (e.g., copper foil). The conductivity of the base layer 4 facilitates heat dissipation from the array 2. The base layer 4 may have a thickness of about 0.0005 inches to about 0.0010 inches. For example, the base layer 4 may be about 0.0007 inches in thickness. An exemplary base layer may be half ounce copper foil.

A non-conductive layer of glue or paste 14 may be used to bond the LED 6 to the base layer 4. The glue layer 14 overlies the base layer 4 and thus is interposed between the base layer 4 and the LED 6. The glue layer 14 may include a reflective material to aide in light emission. In alternative embodiments, the light emitting array 2 may also include a reflective layer disposed below the base layer 4 and the glue layer 14. In such embodiments, the glue layer 14 may comprise an optically clear adhesive, such as silicone, in order to allow for light emitted by the LEDs 6 to be reflected by the reflective layer. The reflective layer may have many different thicknesses and may comprise many different reflective materials, with suitable materials including silver, gold, aluminum, microcellular polyethylene terephthalate (“MCPET”), and diffused light reflector (“DLR”). One of skill in the art will understand that various materials are available for use as an adhesive glue or paste. In another exemplary embodiment, the LED 6 may have bonding pads for adhering the LED 6 to the base layer 4.

In FIG. 5, an array 8 of LEDs is bonded to the base layer 4. However, it will be understood by one of skill in the art that a single LED 6 bonded to the base layer 4 is within the scope of the invention. It will also be understood by one of skill in the art that while only one planar array of LEDs is shown, the LEDs may be positioned on multiple planes and/or layers of the array 2 and in any desired electrical configuration. Bumps or studs 16 may be present on the LEDs 6 for connection with the glue layer 14 and the base layer 4. As seen in FIG. 5, the LEDs 6 are simply placed on the base layer 4 (e.g., no cavity, opening, or void is formed in the base layer 4 for placement of the LED 6).

As will be explained in greater detail below, LEDs 6 in the LED array 8 may be arranged very close to one another on the base layer 4. The close proximity of the LEDs 6 is possible because wire bonding (which is used in surface mount LED applications) is not needed to provide electrical connection to the LEDs 6. Rather, the LEDs 6 may be electrically connected using internal traces making up the LED array 2. As such, the LEDs 6 may be arranged in a near abutting relationship on the base layer 4. For example, the LEDs 6 may be arranged such that about 40 micron (μm) to about 100 micron spacing is present between the LEDs 6. In another example, spacing between the LEDs 6 may be between about 40 μm to about 80 μm, about 50 μm to about 75 μm, about 50 μm to about 70 μm, or about 60 μm to about 70 μm. Close spacing enables more light to be emitted from a relatively smaller sized LED package. One of skill in the art would understand that the internal traces may comprise any suitable material, including copper.

In FIG. 5, the optical layer 10 comprises a transparent material 18 and a luminescent material 12 that is dispersed throughout the transparent material 18. While an optical layer 10 comprising a transparent material 18 having luminescent material 12 that is dispersed throughout the transparent material 18 is shown, alternative embodiments of the light emitting array 2 may include an optical layer 10 solely comprising transparent material 18. The optical layer 10 may be constructed of a thermally conductive material to aid in heat dissipation. The optical layer 10 covers the LED array 8 and the base layer 4. The LEDs 6 of the LED array 8 may be fixed within the array 2 by the optical layer 10. As used herein, “transparent material” may refer to materials that have 100% light transmissivity but also refers to materials that are semi-transparent, as well. The transparent material 18 may be selected to provide different insulating properties. Exemplary transparent materials include epoxy-based or silicone-based materials (e.g., epoxy resin or pre-preg). Pre-preg is a commonly used term in the art meaning “pre-impregnated” composite fibers. Composite structures built of pre-pregs typically require an oven or autoclave to cure. Exemplary pre-preg materials include FR-4 (Woven glass and epoxy), FR-5 (Woven glass and epoxy), FR-6 (Matte glass and polyester), G-10 (Woven glass and epoxy), CEM-3 (Woven glass and epoxy), CEM-4 (Woven glass and epoxy), and CEM-5 (Woven glass and polyester). Exemplary manufacturers and suppliers of thermally conductive pre-preg include Thermagon, Sekisui, Cofan Taiwan, Bergquist, and Denka. Additional transparent materials are well-known and available to persons of skill in the art. In an exemplary embodiment, the optical layer 10 comprises transparent FR-4 having phosphor dispersed throughout the FR-4 material. Other embodiments may comprise an optical layer 10 comprising one or more phosphor layers. The one or more phosphor layers may comprise particles embedded within the array 2 or in a separate medium forming a layer in the array 2.

The thickness of the optical layer 10 may vary, depending on the height of components, such as LEDs, being embedded therein. In an exemplary embodiment, the optical layer 10 may have a thickness of about 0.5 mm to about 1 mm. For example, the optical layer 10 may have a thickness of about 0.5 mm to about 0.75 mm or of about 0.6 mm to about 0.7 mm.

The luminescent material 12 may be dispersed throughout the transparent material 18 of the optical layer 10, such that the luminescent material 12 does not directly coat the LED 6 as a layer of luminescent material. The absence of direct coating of the luminescent material 12 aids in heat dissipation and thermal management for the array 2. The transparent material 18 and luminescent material 12 do not form a composite, but rather the luminescent material 12 is dispersed throughout the transparent material 18. In exemplary embodiments, the luminescent material 12 may be uniformly dispersed throughout the transparent material 18.

The luminescent material 12 may be any desired luminescent material. Persons skilled in the art are familiar with, and have ready access to, a wide variety of luminescent materials. For example, a phosphor is a luminescent material that emits a responsive radiation (e.g., visible light) when excited by a source of exciting radiation. In many instances, the responsive radiation has a wavelength that is different from the wavelength of the exciting radiation. Suitable phosphor materials include, but are not limited to, YAG, TAG, BOSE, and CaSrAlSiN₃. Other examples of luminescent materials include scintillators, day glow tapes and inks that glow in the visible spectrum upon illumination with ultraviolet light.

Luminescent materials can be categorized as being down-converting (i.e., a material which converts photons to a lower energy level (longer wavelength)) or up-converting (i.e., a material which converts photons to a higher energy level (shorter wavelength)). Additionally, in exemplary embodiments, the optical layer 10 may further comprise any of a number of well-known additives (e.g., diffusers, scatterers, tints, etc.).

As detailed in U.S. Pat. No. 7,213,940, hereby incorporated by reference, the combination of LEDs and phosphor may be used to produce a high efficiency white light source that provides an acceptable color temperature, good color rendering index, and a wide gamut. Additionally, it will be appreciated by one of skill in the art that the color of the LEDs, and the color and type of the luminescent materials may be selected to provide the desired light output intensity and color.

The surface 20 of the optical layer 10 may be finished, roughened, patterned, processed, or a surface effect 22 formed therein to aid in obtaining a predetermined light output and improved light extraction. For example, a surface pattern or a region of the surface that is roughened may reside in the surface of the optical layer 10. While such effect is described on the surface of the optical layer 10, the effect 22 may be added to other layers within the array 2 under the surface of the optical layer 10.

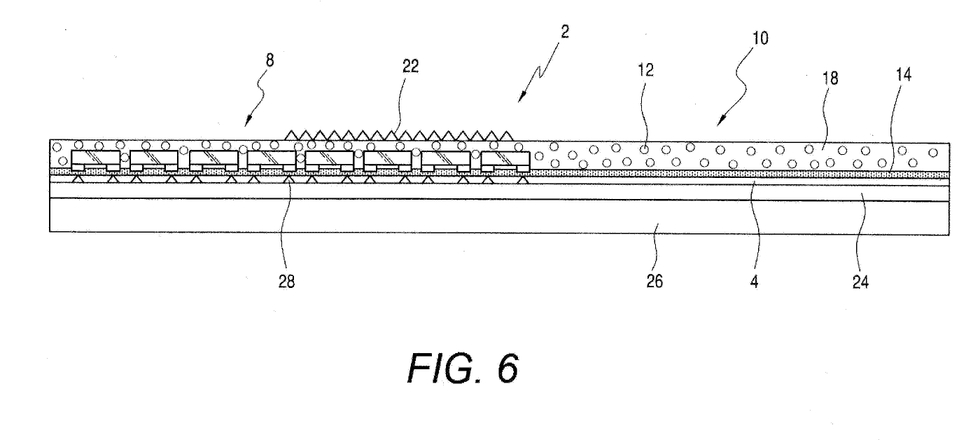

Reference is now made to FIG. 6. FIG. 6 is a side view schematic representation of the light emitting array of FIG. 5 with additional layers added to the array 2. As in FIG. 5, the array 2 comprises the base layer 4, the LED array 8, the glue layer 4, and the optical layer 10. It also comprises a substrate layer 24 disposed below the base layer 4 and a ground plane 26. In FIG. 6, from top to bottom, the sequence of layers includes the optical layer 10, the LED array 8, the glue layer 14, the base layer 4, the substrate layer 24 and the ground plane 26. The substrate layer 24 enables a higher level of integration in the light emitting array 2 by providing a layer that can have additional components embedded therein. For example, all of the driver level circuitry, including the application-specific integrated circuit (ASIC), can be embedded in the substrate layer 24. In other embodiments, the LED array 8 itself may be at least partially embedded in the substrate layer 24, such that the substrate layer 24 is in contract with at least one side portion of the LEDs 6 of the LED array 8.

The substrate layer 24 may comprise ceramic materials, organic insulators, epoxy resin, or pre-preg. In a feature of the aspect, the substrate layer 24 comprises pre-preg material, such as FR-4, FR-5, FR-6, G-10, CEM-3, CEM-4, and CEM-5. In some embodiments, the substrate layer 24 and the optical layer 10 are comprised of the same material. For example, the substrate layer 24 and the optical layer 10 may both be comprised of transparent FR-4 pre-preg material. It will be understood by the skilled person that additional substrate layers may be included in the array depending on the design purposes of the array.

Embedding of additional components into the light emitting array 2 further reduces the size needed for the LED package. Reduction of the total footprint of the LED package is particularly beneficial for smaller form factor applications, such as conventionally-sized light bulbs.

The ground plane 26 may be added to the light emitting array 2 as a thermal management tool. The ground plane 26 size may be adjusted to meet the thermal requirements of the light emitting array 2. The ground plane 26 may comprise a metal foil, such as copper foil. It will be recognized that while the ground plane 26 is in contact with the substrate layer 24 in FIG. 6, it is contemplated that an LED array within the scope of the invention may have the ground plane 26 in contact with the base layer 4 (e.g., in embodiments that do not include a substrate layer or layers).

Micro vias 28 may be formed in the base layer 4 to electrically connect the embedded components, including LEDs 6, to a power source. For example, the vias 28 may be formed in positions that correspond to the bumps or studs 16 formed on the LEDs 6. The vias 28 may be formed by drilling (e.g., using laser or mechanical drilling). The presence of the vias 28 for electrical connection facilitates the absence of wire bonding for providing electrical connection for the LEDs 6. As such, the vias 28 enable closer spacing of the LEDs 6 and thus the ability to have a smaller LED package without sacrificing light output. While FIG. 6 shows an exemplary arrangement of micro vias 28 within the array 2, it will be recognized and understood by the skilled person that other arrangements may be devised consistent with the present teachings, including additional micro vias formed in the substrate layer 24 to further facilitate electrical connection for the LEDs 6 and/or provide further heat dissipation from the LEDs 6. In some embodiments, micro vias 28 formed in the base layer 4 and in the substrate layer 24 may be positioned in a linear configuration. In other embodiments, the micro vias 28 may be positioned in non-linear configurations.

In an exemplary embodiment, the light emitting array 2 is a printed circuit board (PCB) with an LED embedded therein. The printed circuit board may be a single sided printed circuit board or a double sided printed circuit board. The printed circuit board may comprise one or more parallel layers. The printed circuit board may include additional electrical components embedded within the printed circuit board and/or mounted to an outer surface of the printed circuit board. Electrical components may be packaged singly, such as resistors, capacitors, and transistors, or in groups, such as in amplifiers, oscillators, and integrated circuits. In some embodiments, all of the electrical components are embedded within the printed circuit board. In other embodiments, some of the electrical components, such as the drive circuitry, resistors, inductors and capacitors, are embedded within the printed circuit board, while other electrical components are mounted to an outer surface of the printed circuit board. Electronic components may be mounted on an outer surface of the printed circuit board using surface mount technology (SMT). The printed circuit board may be used in a variety of different applications, including, but not limited to, consumer electronics (i.e. televisions, cellular phones, cable television converter boxes, etc.), dedicated service electronics, and high reliability electronics.

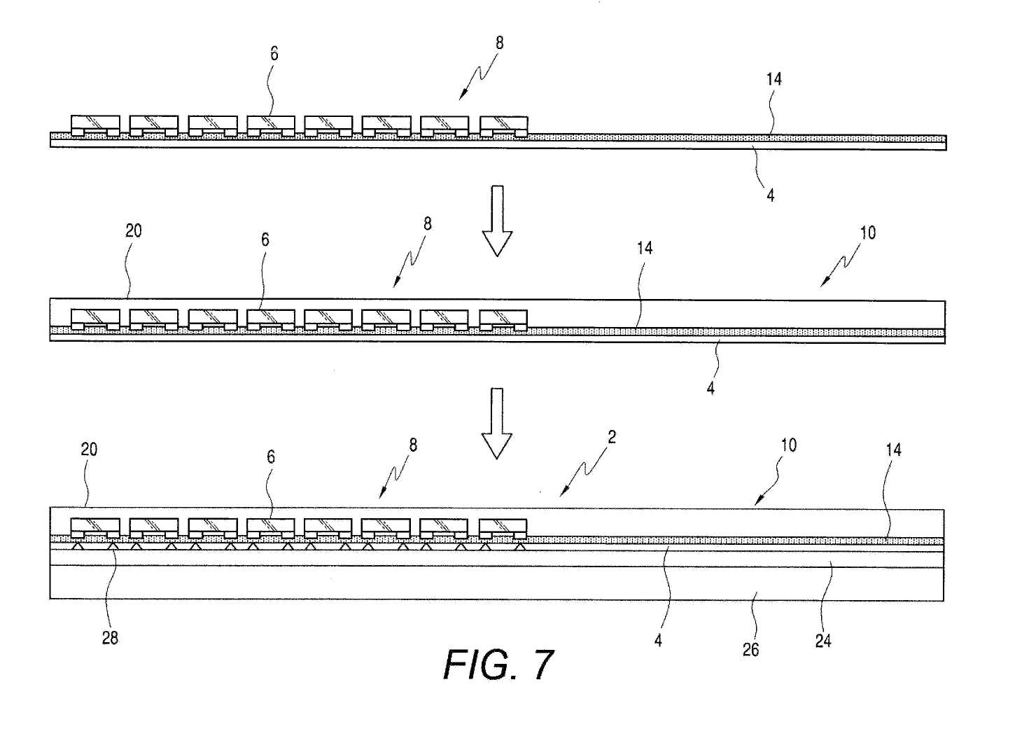

Reference is now made to FIG. 7. FIG. 7 is a series of side view schematic representations of a light emitting array in accordance with the present invention depicting an exemplary process for manufacturing the light emitting array. Printed circuit board processing and assembly are conventionally performed in a clean environment where the air and components can be kept free of contamination. Most electronic manufacturers have their own proprietary processes, but the following process is an exemplary process that may be used to make a two-sided printed circuit board.

In the exemplary process, a base layer 4 is provided and an LED 6 is provided. In FIG. 7, the LED 6 is an LED array 8. For example, the base layer may be a copper panel. Then a reflective glue layer can be applied to the copper panel to form a so-called adhesive-backed copper foil. The LED array can then be placed on the glue layer using conventional methods (e.g., a chip shooter).

Although not illustrated in FIG. 7, the optical layer 10 may be formed as follows. Woven glass fiber is unwound from a roll and fed through a process station where it is impregnated with epoxy resin either by dipping or spraying. For the present invention, this is the stage where the luminescent material (e.g., phosphor) can be added. The impregnated glass fiber then passes through rollers that roll the material to the desired thickness for the finished substrate and also remove any excess resin. The substrate material passes through an oven where it is semicured. After the oven, the material is cut into large panels.

The cut panels can then be stacked in layers, alternating with layers of adhesive-backed copper foil. In the present invention, the optical layer is stacked on the LED array and the base layer (as shown in the center figure in FIG. 7). The stacks are then placed in a press where they are subjected to temperatures of about 340° F. (170° C.) and pressures of 1500 psi for an hour or more. This fully cures the resin and tightly bonds the copper foil to the surface of the substrate material. In an exemplary embodiment, the optical layer may be a FR-4 pre-preg with phosphor dispersed therein.

The following steps can be used to drill and plate holes or micro vias. Several panels of substrate or optical layer/base layer, each large enough to make several printed circuit boards, are stacked on top of each other and pinned together to keep them from moving. The stacked panels are placed in a CNC machine, and the holes are drilled according to the pattern determined when the boards were laid out. The holes are then deburred to remove any excess material clinging to the edges of the holes. The inside surfaces of the holes that are designed to provide a conductive circuit from one side of the board to the other are plated with copper. Non-conducting holes are plugged to keep them from being plated or are drilled after the individual boards are cut from the larger panel.

The following steps may be used to create a printed circuit pattern on the optical layer/base layer composite. The printed circuit pattern may be created by an “additive” process or a “subtractive” process. In the additive process, copper is plated, or added, onto the surface of the substrate in the desired pattern, leaving the rest of the surface unplated. In the subtractive process, the entire surface of the substrate is first plated, and then the areas that are not part of the desired pattern are etched away, or subtracted.

The following steps may be used for the additive process. The copper foil surface of the substrate or the optical layer/base layer composite is degreased. The panels pass through a vacuum chamber where a layer of positive photoresist material is pressed firmly onto the entire surface of the foil. A positive photoresist material is a polymer that has the property of becoming more soluble when exposed to ultraviolet light. The vacuum ensures that no air bubbles are trapped between the foil and the photoresist. The printed circuit pattern mask is laid on top of the photoresist and the panels are exposed to an intense ultraviolet light. Because the mask is clear in the areas of the printed circuit pattern, the photoresist in those areas is irradiated and becomes soluble. The mask is removed, and the surface of the panels is sprayed with an alkaline developer that dissolves the irradiated photoresist in the areas of the printed circuit pattern, leaving the copper foil exposed on the surface of the substrate. The panels are then electroplated with copper. The foil on the surface of the substrate acts as the cathode in this process, and the copper is plated in the exposed foil areas to a thickness of about 0.001-0.002 inches (0.025-0.050 mm). The areas still covered with photoresist cannot act as a cathode and are not plated. Tin-lead or another protective coating is plated on top of the copper plating to prevent the copper from oxidizing and as a resist for the next manufacturing step. The photoresist is stripped from the boards with a solvent to expose the substrate's copper foil between the plated printed circuit pattern. The boards are sprayed with an acid solution that eats away the copper foil. The copper plating on the printed circuit pattern is protected by the tin-lead coating and is unaffected by the acid.

Additionally, the surface 20 of the optical layer 10 may be finished to obtain a predetermined light output. Surface finishing may include providing surface patterns or providing a roughened area in a portion of the surface. It will be understood by one of skill in the art that in alternative embodiments, other layers within the array 2 may be the finished, roughened, patterned, and/or processed to provide an effect under the surface of the optical layer 10.

If more layers are desired, additional substrate layers may be added to the optical layer/base layer composite in the manner described above. For example, the above-described composite may be flipped over for application of a substrate layer onto the base layer and/or for drilling of micro vias in the base layer to enable electrical connection to the LED array 8 and other components. One of skill in the art will understand how to build layers as desired. Additional components (e.g., driver circuitry) may be embedded in the substrate layer 24. A ground plane 26 may also be applied to the substrate layer 24. The size of the ground plane 26 is variable and may be adjusted based on the thermal requirements.

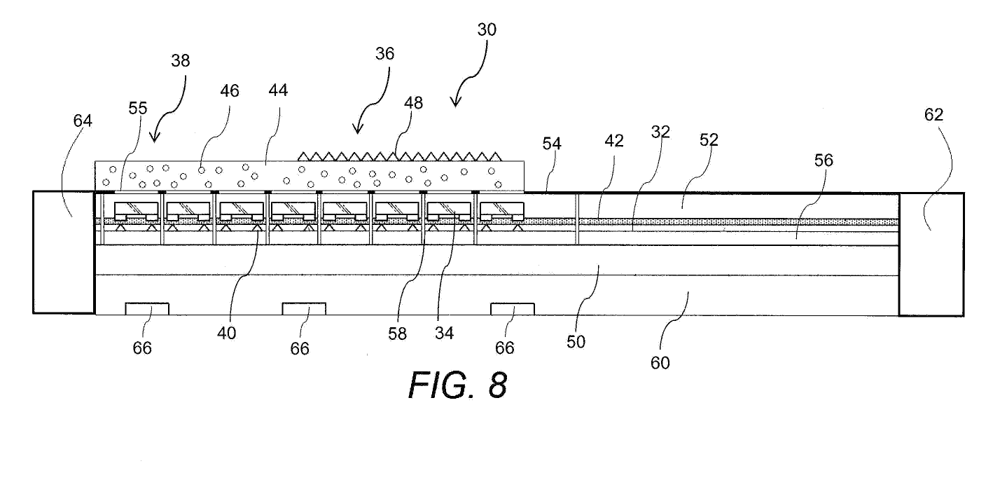

Reference is now made to FIG. 8. FIG. 8 is a side view schematic representation of an alternative embodiment of a light emitting array 30 in accordance with the present invention. The light emitting array 30 comprises a base layer 32, an array 36 of LEDs 34 disposed on the base layer 32, and an optical layer 38 covering the array 36 of LEDs 34 and the base layer 32. A glue layer 42 may be applied to the base layer 32, and the LED array 36 may be placed on the glue layer 42 using conventional methods. The light emitting array 30 also comprises a ground plane 50 disposed below the base layer 32 and a first substrate layer 52. In this embodiment, the LED array 36 is embedded within the first substrate layer 52 such that the first substrate layer 52 is adjacent to and in contact with the LED array 36 and the base layer 32. In this embodiment, the first substrate layer 52 may comprise a transparent material, such as transparent epoxy resin or pre-preg. Micro vias 40 may be formed in the base layer 32 to electrically connect the embedded components to a power source. A second substrate layer 56 is disposed below the base layer 32 and is in contact with the ground plane 50.

The optical layer 38 comprises a transparent material 44 having luminescent material 46 disposed therein. In some embodiments, the transparent material 44 may be a transparent epoxy resin or pre-preg material. The luminescent material 46 may comprise any suitable material, including phosphor. The surface of the optical layer 38 may be finished or a surface effect 48 formed therein to aid in obtaining a predetermined light output and diffusing light. For example, a surface pattern or a region of the surface that is roughened may reside on the surface of the optical layer.

As shown, the optical layer 38 is separate from the embedded LED array 36. The optical layer 38 may be separated from the embedded LED array 36 in order to control the amount of heat produced by the luminescent material 46 and the LED array 36. For example, in embodiments where the luminescent material 46 is phosphor, the phosphor may produce greater amounts of heat than the LEDs 34. The light emitting array 30 includes a copper panel 54, or trace, disposed between the optical layer 38 and the embedded LED array 36 within the first substrate layer 52. The copper panel 54 may be used as a means to dissipate heat generated by the optical layer 38 during use of the light emitting array 30. The copper panel 54 is disposed over the first substrate layer 52 and includes openings 55 to allow light emitted by the LEDs 34 of the LED array 36 to pass through the first substrate layer 52 and into the optical layer 38. Thermal paths 58 may be drilled through the copper panel 54 and the first substrate layer 52 to the ground plane 50 to help with heat dissipation. As shown, a portion of the copper panel 54 is not covered by the optical layer 38. This portion of the copper panel 54 may also be used to aid heat dissipation from the optical layer 38. Additional heat sinks 62, 64 are disposed on the light emitting array 30 in contact with the ground plane 50. The heat sinks 62, 64 may be made from material having high thermal conductivity such as aluminum, copper, ceramics, plastics, composites, or a combination of these materials. In other embodiments, additional ground planes may also be included in the light emitting array 30 in order to better facilitate heat dissipation.

A third substrate layer 60 is disposed below the ground plane 50. The third substrate layer 60 enables a higher level of integration in the light emitting array 30 by providing layers that may have additional components embedded therein. As shown, components 66, such as the ASIC, are embedded in the third substrate layer 60. Additional components, including supporting components such as resistors, inductors, and capacitors may also be embedded within the third substrate layer 60. It will be understood by the skilled person that multiple ground planes and substrate layers may be included in the array depending on the design purposes of the array.

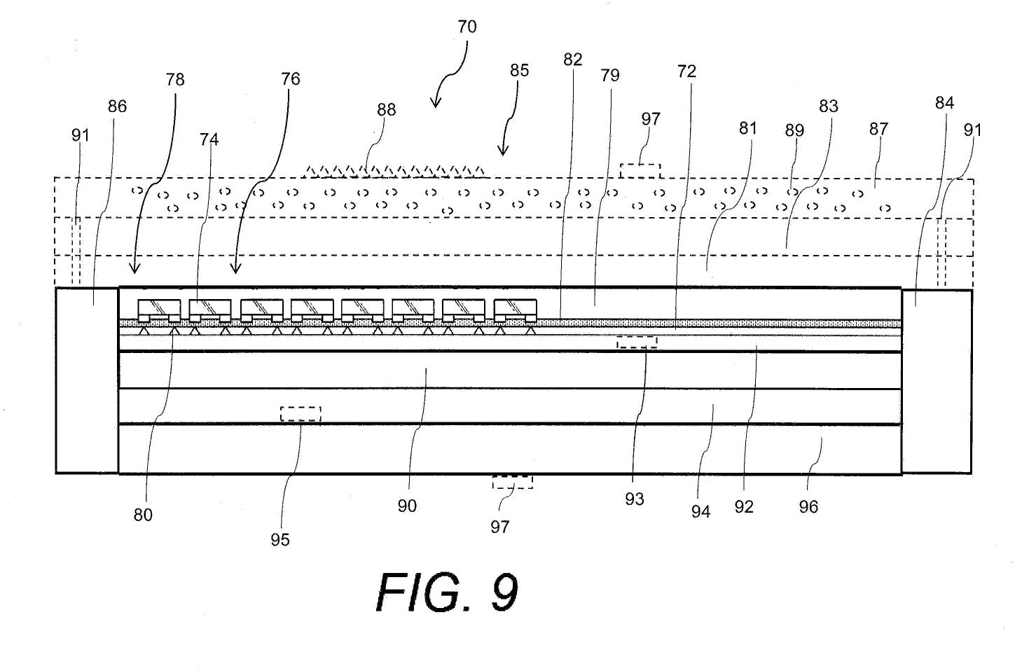

Reference is now made to FIG. 9. FIG. 9 is a side view schematic representation of an alternative embodiment of a light emitting array 70 in accordance with the present invention. The light emitting array 70 comprises a base layer 72, and an array 76 of LEDs 74 disposed on the base layer 72, and an optical layer 78 covering the array 76 of LEDs 74 and the base layer 72. A glue layer 82 may be applied to the base layer 72 and the LED array 76 may then be placed on the glue layer 82 using conventional methods (e.g., a chip shooter). The light emitting array 70 also comprises a ground plane 90 disposed below the base layer 72. Micro vias 80 may be formed in the base layer 72 to electrically connect the embedded components to a power source. Heat sinks 84, 86 are disposed on the light emitting array 70 in contact with the ground plane 90. The heat sinks 84, 86 may be made from material having high thermal conductivity such as aluminum, copper, ceramics, plastics, composites, or a combination of these materials.

The optical layer 78 comprises a transparent material 79. In some embodiments, the transparent material 79 may be an epoxy resin or pre-preg material. As shown in FIG. 9, the light emitting array 70 may include an optional transparent layer 81, an optional spacer layer 83, and an optional luminescent layer 85 disposed above the optical layer 78. The dashed lines indicate the optional nature of the transparent layer 81, spacer layer 83, and the luminescent layer 85. As shown, the transparent layer 81 is disposed above the optical layer 78. In some embodiments, the transparent layer 81 may comprise materials such as plastic, silicon, glass, epoxy-resin, and pre-preg materials. The spacer layer 83 is disposed between the transparent layer 81 and the luminescent layer 85. The spacer layer 83 may comprise transparent material such as silicone, epoxy resin, oil, dielectrics, and other materials. The spacer layer 83 may provide further separation between the array 76 of LEDs 74 from the luminescent layer 85, which may provide additional heat dissipation. The luminescent layer 85 is disposed above the transparent layer 81. The luminescent layer 85 may comprise a transparent material 87 having luminescent material 89 disposed through the transparent material 87. Suitable luminescent material 89 may include phosphors, scintillators, day glow tapes and inks that glow in the visible spectrum upon illumination with ultraviolet light. In one exemplary embodiment, the luminescent material 89 is a phosphor. The surface of the luminescent layer 85 may be finished, roughened, patterned, processed, or an optional surface effect 88 formed therein (as indicated by dashed lines) to aid in obtaining a predetermined light output and improved light extraction. For example, a surface pattern or a region of the surface that is roughened may reside in the surface of the optical layer 78. It will be understood by one of skill in the art that the surface pattern or a region of the surface may be disposed on the surface of the luminescent layer 85, or disposed in a separate layer of the light emitting array 70 below the luminescent layer 85. Optional thermal paths 91 (as indicated by the dashed lines) may be drilled through the luminescent layer 85, the spacer layer 83, and the transparent layer 81 in order to allow heat dissipation from the luminescent layer 85 to the heat sinks 84, 86. It will be understood by the skilled person that one or more of the optional layers may be included depending on the design purposes of the array 70.

The light emitting array 70 includes a first substrate layer 92, a second substrate layer 94, and a third substrate layer 96. The first substrate layer 92, the second substrate layer 94, and the third substrate layer 96 may comprise a transparent material, such as transparent epoxy resin or pre-preg. The first substrate layer 92 is disposed below the base layer 72 and is in contact with the ground plane 90. The second substrate layer 94 is disposed beneath the ground plane 90 and the third substrate layer 96 is disposed beneath the second substrate layer 94. The first substrate layer 92, the second substrate layer 92, and the third substrate layer 96 enable a higher level of integration in the light emitting array 70 by providing layers that may have additional components embedded therein. While the embodiment shown in FIG. 9 comprises a first substrate layer 92, a second substrate layer 94, and a third substrate layer 96, it will be understood by one of skill in the art that the array 70 may include more or less substrate layers.

The light emitting array 70 may also include optional electrical components 93, 95, and 97 (as indicated by dashed lines). As shown, electrical components 93 and 95 are embedded within the first substrate layer 92 and the second substrate layer 94, respectively. Components 93 and 95 may comprise the driver level circuitry, including the ASIC, or other active components for operation of the light emitting array 70. In addition, supporting components, such as resistors, capacitors, and inductors, may also be embedded within the light emitting array 70. Components 97 are mounted to outer surfaces of the light emitting array 70. Components 97 may comprise active components and passive components for operation of the array 70, as well as, as components such as transistors, oscillators, or additional LEDS may be mounted to the outer surfaces of the light emitting array 70. Components 97 may be mounted to the outer surfaces of the light emitting array 70 using surface mount technology. One of skill will understand that optional components 93, 95, and 97 may be disposed within the light emitting array in all of the places indicated in FIG. 9, or all in one place within and/or upon the light emitting array 70. For example, all of the components may be embedded within the first substrate layer 92.

In the drawings and specification, there have been disclosed typical embodiments of the invention and, although specific terms are employed, they are used in a generic and descriptive sense only and not for purposes of limitation, the scope of the invention being set forth in the following claims.

1. A light emitting array, comprising:
(a) a submount having a top surface and a bottom surface, and
(b) at least one LED at least partially embedded within the submount;
wherein the top surface of the submount is in contact with at least a side surface of the at least one LED.

2. The array of claim 1, wherein the at least one LED is completely embedded in the submount.

3. The array of claim 1, wherein the submount comprises a transparent epoxy resin pre-preg material.

4. The array of claim 1, wherein the submount comprises one or more parallel layers.

5. The array of claim 4, further comprising a base layer in contact with the at least one LED.

6. The array of claim 5, further comprising a glue layer bonding the at least one LED to the base layer, wherein the glue layer overlies the base layer.

7. The array of claim 4, further comprising micro vias disposed through the one or more parallel layers of the submount.

8. The array of claim 4, further comprising an optical layer covering the at least one LED in such a way that light emitted from the at least one LED passes through the optical layer.

9. The array of claim 8, wherein the optical layer comprises a transparent material having a luminescent material dispersed therein.

10. The array of claim 9, wherein the luminescent material comprises phosphor.

11. The array of claim 8, wherein the optical layer comprises transparent epoxy resin having phosphor dispersed therein.

12. The array of claim 1, wherein the at least one LED comprises an array of LEDs.

13. The array of claim 12, wherein spacing between the LEDs in the array is between about 40 microns to about 100 microns.

14. The array of claim 1, further comprising a ground plane.

15. The array of claim 4, further comprising a substrate layer disposed below the at least one LED.

16. The array of claim 15, wherein a component is embedded within the substrate layer.

17. The array of claim 16, wherein the component is drive circuitry.

18. The array of claim 8, wherein a surface effect resides on a surface of the optical layer such that the array produces a predetermined light output.

19. The array of claim 18, wherein the surface effect comprises a roughened surface region.

20. The array of claim 18, wherein the surface effect comprises a surface pattern.

21. The array of claim 1, wherein the light emitting array comprises a printed circuit board with at least one LED embedded therein.

22. The array of claim 21, wherein a component is mounted to an outer surface of the printed circuit board.

23. A process for manufacturing a light emitting array, the process comprising
(a) providing at least one LED; and
(b) at least partially embedding the at least one LED within a submount.

24. The process of claim 23, further comprising stacking an optical layer in covering relation to the at least one LED.

25. The process of claim 24, wherein the optical layer comprises a transparent material including a luminescent material dispersed therein.

26. The process of claim 23, further comprising placing the at least one LED on a base layer prior to the embedding step.

27. The process of claim 26, further comprising drilling a micro via in the base layer.

28. The process of claim 26, further comprising adding a ground plane to the light emitting array, wherein the ground plane is disposed below the at least one LED and the base layer.

29. The process of claim 23, wherein a top surface of the submount is in contact with at least a side surface of the at least one LED.

30. The process of claim 23, wherein the at least one LED is completely embedded within the submount.

31. The process of claim 23, wherein the light emitting array comprises a printed circuit board having at least one LED embedded therein.

32. The process of claim 26, wherein the at least one LED is bonded to the base layer by a glue layer overlying the base layer.

33. The process of claim 25, wherein the luminescent material comprises phosphor.
